(19) United States
(12) Patent Application Publication
(10) Pub. No.: US 2007/0022953 A1
(43) Pub. Date: Feb. 1, 2007

(54) Source gas-supplying unit and chemical vapor deposition apparatus having the same

(75) Inventors: Yun-Ho Choi, Yongin-si (KR); Tae-Hong Ha, Hwaseong-si (KR); Jung-Hun Seo, Suwon-si (KR); Jin-Gi Hong, Suwon-si (KR); Jung-Suk Seo, Suwon-si (KR); Sung-Guen Park, Hwaseong-si (KR); Hyun-Chul Kwun, Hwaseong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/490,246

(22) Filed: Jul. 21, 2006

(30) Foreign Application Priority Data
Jul. 27, 2005 (KR) 2005-0068296

(51) Int. Cl. C23C 16/00

(52) U.S. Cl. 118/715

(57) ABSTRACT

A source gas-supplying unit may include a chamber for receiving a liquid source. A first pipe may extend into the chamber to dip into the liquid source. The first pipe may provide a carrier gas to bubble through the liquid source to generate a vapor source. A second pipe may be connected to the chamber. The vapor source and the carrier gas may be supplied by the second pipe to a process chamber in which a semiconductor-manufacturing process may be carried out. A blocking structure may be provided in the sealed chamber. The blocking structure may block the liquid source that may be splashed toward the second pipe due to the bubbling.

### PRIORITY STATEMENT

This application claims priority under 35 USC § 119 from Korean Patent Application No. 2005-68296, filed on Jul. 27, 2005, the contents of which are herein incorporated by reference in their entirety.

### BACKGROUND

1. Field of the Invention

Example embodiments of the present invention may relate generally to a source gas-supplying unit for supplying a source gas, which may be used in a chemical vapor deposition process (for example), to a process chamber. More particularly, example embodiments of the present invention may relate to a source gas-supplying unit for supplying a source gas, which may be generated by bubbling a liquid source, to a process chamber.

2. Description of the Related Art

A semiconductor device may be manufactured by implementing various processes. For example, a fabrication process may be employed to form an electrical circuit, which may include electrical elements, on a semiconductor substrate, such as a silicon wafer (for example). An electrical die sorting (EDS) process may be employed to test various electrical characteristics of the semiconductor device on the semiconductor substrate. A packaging process may be employed to encapsulate the semiconductor device using an epoxy resin and to singulate the wafer into individual chips.

The fabrication process may include a deposition process for forming a layer on the substrate, a chemical mechanical polishing process for planarizing a surface of the layer using a slurry (for example), a photolithography process for forming a photoresist pattern on the layer, an etching process for forming a pattern having electrical characteristics from the layer using the photoresist pattern as an etching mask, an ion implantation process for implanting ions into designated regions of the substrate, a cleaning process for removing contaminants from the substrate, and an inspection process for inspecting a surface of the substrate supporting the layer and/or pattern.

Reaction gases may be used in the above-mentioned fabrication processes. The reaction gases may be generated and/or filtered in a gas-supplying apparatus. The reaction gases may be supplied to a process chamber. Conventional apparatuses may include a sealed chamber that may have an inlet and an outlet.

According to convention, a liquid source may be evaporated to generate a source gas that may be used for forming a layer on a wafer in the deposition process. The source gas may be provided to a deposition chamber. To generate the source gas from the liquid source, an evaporator and/or a carrier gas may be implemented.

FIG. 1 is a cross sectional view of a conventional source gas-supplying unit implementing a carrier gas.

Referring to FIG. 1, a conventional source gas-supplying unit 1 may include a sealed chamber 10 in which a liquid source 12 may be received. A heater 50 for heating the liquid source 12 may be positioned beneath the chamber 10. A carrier gas-supplying pipe 20 may be connected to an upper face of the chamber 10. The carrier gas-supplying pipe 20 has a lower end that enters in the chamber 10. The lower end of the carrier gas-supplying pipe 20 may be dipped into the liquid source 12. The liquid source 12 may be evaporated by bubbling of a carrier gas provided through the carrier gas-supplying pipe 20 and the heater 50 to generate a vapor source in the chamber 10. The vapor source may be supplied to a process chamber (not shown) through a source gas-supplying pipe 30 together with the carrier gas. A liquid source-supplying pipe 40 for supplying the liquid source 12 to the chamber 10 may be connected to the upper face of the chamber 10.

Although conventional source gas-supplying units are generally thought to provide acceptable results, they are not without shortcomings. For example, when the carrier gas is bubbled through the liquid source 12, the liquid source 12 may be splashed. An inner face of the source gas-supplying pipe 30 may be smeared with the splashed liquid source 12. When the inner face of the source gas-supplying pipe 30 is smeared with the splashed liquid source, a cross sectional area of the source gas-supplying pipe 30 may be reduced. The source gas-supplying pipe 30 may be clogged with the splashed liquid source 12. As a result, the source gas may not flow through the source gas-supplying pipe 30 as intended, so that failures may be generated in the deposition process.

### SUMMARY

According to an example embodiment, a source gas-supplying unit may include a chamber for receiving a liquid source. A first pipe may extend into the chamber to dip into the liquid source. The first pipe may supply a carrier gas that may be bubbled through the liquid source to generate a source gas. A second pipe may be connected to the chamber. The second pipe may supply the source gas and the carrier gas to a process chamber. A blocking structure may be arranged in the chamber. The blocking structure may block the liquid source splashed toward the second pipe.

According to another example embodiment, a chemical vapor deposition (CVD) apparatus may include a process chamber for receiving a wafer. A source gas-supplying unit may include a chamber for receiving a liquid source. A first pipe may extend into the chamber to dip into the liquid source. The first pipe may supply a carrier gas that may be bubbled through the liquid source to generate a source gas. A second pipe may be connected to the sealed chamber. The second pipe may supply the source gas and the carrier gas to the process chamber. A blocking structure may be arranged in the chamber. The blocking structure may block the liquid source splashed toward the second pipe.

According to another example embodiment, a source gas-supplying unit may include a chamber to contain a liquid. A first conduit may extend into the chamber. The first conduit may supply a carrier gas into the liquid to generate a source gas. A second conduit may have an end connected to the chamber. Means may be provided for deflecting liquid splashed toward the second pipe.

### BRIEF DESCRIPTION OF THE DRAWINGS

Example, non-limiting embodiments of the invention will become apparent by reference to the following detailed description when considered in conjunction with the accompanying drawings

FIG. 1 is a cross sectional view of a conventional source gas-supplying unit.

FIG. 2 is a cross sectional view of a source gas-supplying unit in accordance with an example, non-limiting embodiment of the present invention.

FIG. 3 is a perspective view of a blocking structure in FIG. 2.

FIG. 4 is a perspective view a blocking structure in accordance with another example, non-limiting embodiment of the present invention.

FIG. 5 is a cross sectional view of a chemical vapor deposition apparatus in accordance with another example, non-limiting embodiment of the present invention.

FIG. 6 is a graph illustrating a deposition thickness per the number of a wafer on which a deposition process is carried out using the conventional source gas-supplying unit in FIG. 1.

FIG. 7 is an image from a scanning electron microscope (SEM) of a layer on the wafer that is formed using the conventional source-gas supplying unit in FIG. 1.

FIG. 8 is a graph illustrating a deposition thickness per the number of a wafer on which a deposition process is carried out using the source gas-supplying unit in FIG. 2.

FIG. 9 is an image from a scanning electron microscope (SEM) of a layer on the wafer that is formed using the source-gas supplying unit in FIG. 2.

### DESCRIPTION OF EXAMPLE, NON-LIMITING EMBODIMETS

Example, non-limiting embodiments of the present invention are described with reference to the accompanying drawings. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. The principles and features of this invention may be employed in varied and numerous embodiments without departing from the scope of the present invention. In the drawings, the size and relative sizes of layers and regions may be exaggerated for clarity. The drawings are not to scale. Like reference numerals refer to like elements throughout

It will be understood that when an element or layer is referred to as being “on,” “connected to” and/or “coupled to” another element or layer, it can be directly on, connected and/or coupled to the other element or layer or intervening elements or layers may be present. In contrast, when an element is referred to as being “directly on,” “directly connected to” and/or “directly coupled to” another element or layer, there may be no intervening elements or layers present As used herein, the term “and/or” includes any and all combinations of one or more of the associated listed items.

Although the terms first, second, etc. may be used herein to describe various elements, components, regions, layers and/or sections, these elements, components, regions, layers and/or sections should not be limited by these terms. These terms may be used to distinguish one element, component, region, layer and/or section from another element, component, region, layer and/or section. For example, a first element, component, region, layer and/or section discussed below could be termed a second element, component, region, layer and/or section without departing from the teachings of the present invention.

Spatially relative terms, such as “beneath,” “below,” “lower,” “above,” “upper” and the like, may be used to describe one element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (rotated 90 degrees or at other orientations) and the spatially relative descriptors used herein interpreted accordingly.

The terminology used herein is for the purpose of describing example embodiments only and is not intended to be limiting of the invention. As used herein, the singular terms “a,” “an” and “the” are intended to include the plural forms as well, unless the context clearly indicates otherwise. It will be understood that the terms “includes” and/or “including,” when used in this specification, specify the presence of stated features, integers, steps, operations, elements, and/or components, but do not preclude the presence and/or addition of one or more other features, integers, steps, operations, elements, components, and/or groups thereof.

Unless otherwise defined, all terms (including technical and scientific terms) used herein may have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized and/or overly formal sense unless expressly so defined herein.

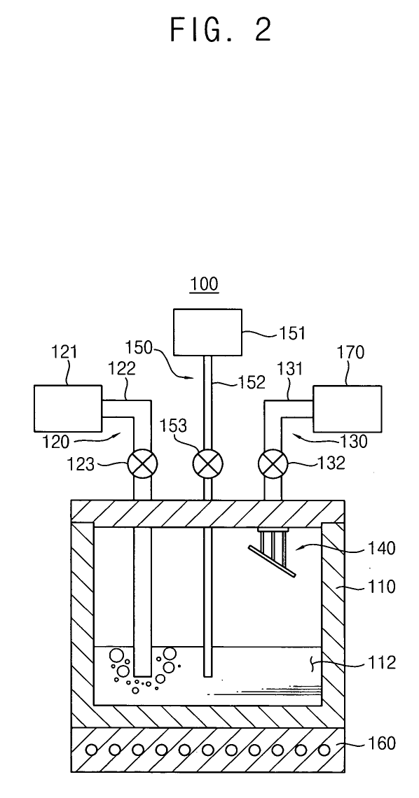

FIG. 2 is a cross sectional view of a source gas-supplying unit in accordance with an example embodiment of the present invention.

Referring to FIG. 2, a source gas-supplying unit 100 may include a sealed chamber 110, a first gas-supplying unit 120, a second gas-supplying unit 130, a blocking structure 140, a liquid source-supplying unit 150 and a heater 160.

The sealed chamber 110 may have a hollow cylindrical shape or a hollow hexahedral shape. A sealed chamber 110 having an alternative shape may be suitably implemented. The sealed chamber 110 may receive a liquid source 112.

By way of example only, the liquid source may include an organic metal compound for forming a metal layer by a chemical vapor deposition (CVD) process. An example of an organic metal compound for forming an aluminum layer may include an aluminum precursor such as dimethyl aluminum hydride (DMAH), dimethyl ethyl amine alane (DMEAA), methyl pyrrolidine alane (MPA), etc. The MPA may be used as the aluminum precursor.

The heater 160, which may heat the liquid source 112, may be positioned under a lower face of the sealed chamber 110. The heated liquid source 112 may be evaporated by a carrier gas.

The first gas-supplying unit 120 may supply the carrier gas into the sealed chamber 110. The first gas-supplying unit 120 may include a first tank 121, a first pipe 122 and a first valve 123.

The first tank 121 may contain the carrier gas. An example of the carrier gas may include an inert gas such as a nitrogen gas, an argon gas, a helium gas, etc.

The first pipe 122 may be connected between the first tank 121 and the sealed chamber 110. The first pipe 122 may penetrate an upper face of the sealed chamber 110. Further, the first pipe 122 may be submerged in the liquid source 112 in the sealed chamber 110. The carrier gas provided through the first pipe 122 may create bubbles in the liquid source 112. The heat from the heater 160 and the bubbles of carrier gas may readily evaporate the liquid source 112 to generate a source gas.

The first valve 123 may be installed in a portion of the first pipe 122 at an outside of the sealed chamber 110. The first valve 123 may open and close the first pipe 122. The first valve 123 may control a flux of the carrier gas flowing through the first pipe 122.

To supply a heated carrier gas into the sealed chamber 110, a second heater (not shown) for heating the carrier gas (e.g., a heating jacket) may be provided to an outer face of the first pipe 122.

The second gas-supplying unit 130 may provide a process chamber 170 with the source gas and the carrier gas in the sealed chamber 110. The second gas-supplying unit 130 may include a second pipe 131 and a second valve 132.

The second pipe 131 may be connected between the sealed chamber 110 and the process chamber 170. By way of example only, a CVD process, which may form a layer on a wafer using the source gas, may be carried out in the process chamber 170.

The second pipe 131 may be connected to the upper face of the sealed chamber 110. The carrier gas and the source gas may be supplied to the process chamber 170 through the second pipe 131.

The second valve 132 may be installed in the second pipe 131. The second valve 132 may open and close the second pipe 131. An opening angle of the second valve 132 may be adjusted in accordance with a procedure of the CVD process in the process chamber 170. Further, the opening angle of the second valve 132 may be adjusted in accordance with a thickness of the layer on the wafer. Furthermore, the second valve 132 may control a flux of the source gas flowing through the second pipe 131.

When the carrier gas is bubbled through the liquid source 112, the liquid source 112 may be splashed. The blocking structure 140 may block (or redirect) the liquid source 112 splashed toward the second pipe 131, which may prevent the second pipe 131 from being clogged with the splashed liquid source 112. The blocking structure 140 may be considered as a deflector to the extent that it redirects the liquid source 112 splashed toward the second pipe 131.

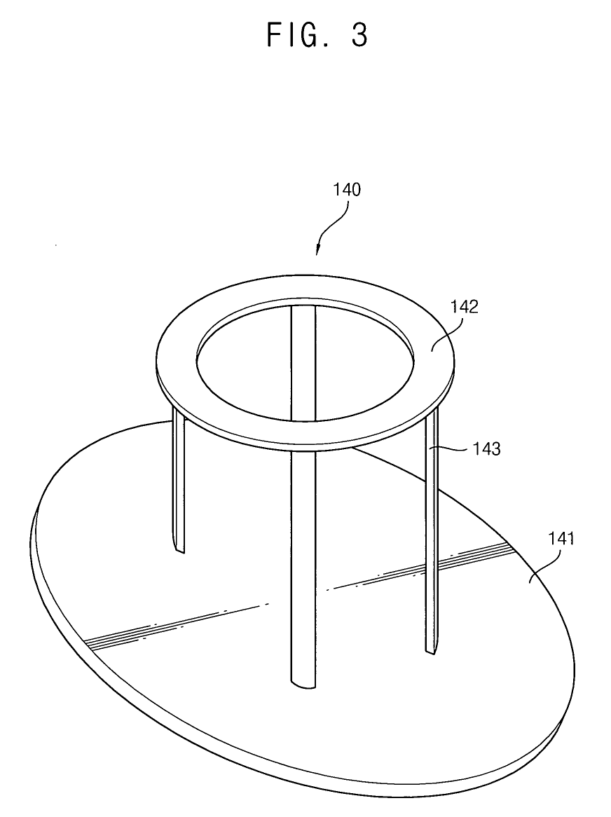

FIG. 3 is a perspective view of the blocking structure 140 in FIG. 2.

Referring to FIG. 3, the blocking structure 140 may include a blocking member (or deflector) 141, a fixing member 142 and a connecting member 143.

The blocking member 141 may be in the form of a circular plate. The blocking member 141 may be arranged between a position where the liquid source 112 is splashed by the bubbling of the carrier gas and a position where the second pipe 131 is connected to the sealed chamber 110. The blocking member 141 may block off (and redirect) the travel path of the liquid source 112 splashed toward the second pipe 131. The blocking member 141 may have an area larger than the cross sectional area of the second pipe 131.

In alternative embodiments, the blocking member 141 may include a first portion through which the source gas and the carrier gas pass, and a second portion connected to an inner wall of the sealed chamber 110.

In this example embodiment, the liquid source 112 may be splashed from a position that may be offset from a vertical axis of the second pipe 131. Thus, the blocking member 141 may have an inclined lower face that may face toward the position from which the liquid source 112 may be splashed. The splashed liquid source 112 that may impinge upon (and may be blocked by) the blocking member 141 may flow along the inclined lower face of the blocking member 141 and may fall back into the pool of liquid source 112 in the sealed chamber 110.

By way of example only, the fixing member 142 may have an annular shape. In alternative embodiments, a fixing member 142 having some other geometric shape may be suitably implemented. The annular fixing member 142 may be fixed to the inner wall of the sealed chamber 110 that corresponds to an edge of the position of the where the second pipe 131 may be connected to the sealed chamber 110. The fixing member 142 may be fixed to the inner wall of the sealed chamber 110 using a screw, for example.

By way of example only, the connecting member 143 may have a bar shape. In alternative embodiments, the connecting member 143 having some other geometric shape may be suitably implemented. The number of the connecting member 143 may be at least two. The connecting member 143 may be connected between the blocking member 141 and the fixing member 142. The connecting member 143 may support the blocking member 141 spaced apart from the inner wall of the sealed chamber 110. The source gas and the carrier gas may be supplied to the second pipe 131 through a space between the connection members 143.

The blocking member 141, the fixing member 142 and the connecting member 143 may be of a unitary, one-piece construction or alternatively, provided as individual component parts that may be assembled together.

By way of example only, the blocking member 141, the fixing member 142 and the connecting member 143 may be fabricated from a high temperature-resistant material such as a stainless steel, a ceramic, etc.

Surfaces of the blocking member 141, the fixing member 142 and the connecting member 143 may be coated with TEFLON, for example. The TEFLON may have a high temperature-resistant characteristic and/or non-viscosity. The term “non-viscosity” means that TEFLON may provide an anti-stick feature. Thus, the liquid source 112 that may be splashed onto the blocking member 141 may not stick on the blocking member 141. As a result, the liquid source 112 on the blocking member 141 may drop into the liquid source 112 pooled in the bottom of the sealed chamber 110.

As described above, the blocking structure 140 may block the liquid source 112 that may be splashed toward the second pipe 131. The carrier gas and the source gas generated by bubbling the carrier gas through the liquid source 112 may be supplied to the second pipe 131 through the blocking structure 140. In this way, the cross sectional area of the second pipe 131 may be maintained and the second pipe 131 may not be clogged via accumulation of the splashed liquid source 112. As a result, the source gas and the carrier gas may be provided to the process chamber 170 through the second gas-supplying unit 130.

The blocking structure 140 may be employed for blocking the liquid sources 112 having various viscosities. The blocking structure 140 may be employed for blocking the liquid source having a viscosity of about 30 cP (centi-poise). When the viscosity of the liquid source 112 is above about 30 cP, the splashed liquid source 112 may not reach the second pipe 131 due to the high viscosity of the liquid source 112. Thus, there may be no effect produced by the blocking structure 140.

When the viscosity of the liquid source 112 is below about 30 cP, the liquid source 112 may be more vigorously splashed due to bubbling the carrier gas. The splashed liquid source 112 may splash with enough velocity to reach the second pipe 131. Thus, an effect produced from the blocking structure 140 may be realized.

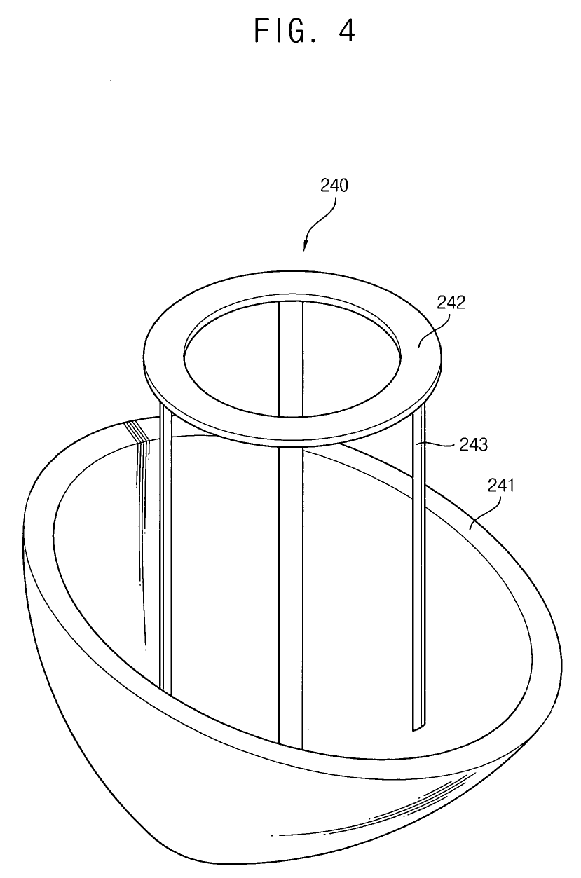

FIG. 4 is a perspective view of a blocking structure in accordance with another example, non-limiting embodiment of the present invention.

Referring to FIG. 4, the blocking structure 240 may include a blocking member 241, a fixing member 242 and a connecting member 243. Here, the fixing member 242 and the connecting member 243 may be substantially similar to the fixing member 142 and the connecting member 143 of FIG. 3.

The blocking member 241 may have an arcuate shape (e.g., a semi-spherical shape). The blocking member 242 may have a curved outer face that may face a position from which the liquid source may be splashed. The liquid source that may land on the blocking member 241, may flow along the curved outer face of the blocking member 241 and may drop into the liquid source pooled at the bottom of the sealed chamber.

In the example embodiments, the blocking member may have the circular plate shape or the arcuate shape. In alternative embodiments, the blocking member may have numerous other shapes for blocking (and/or deflecting) the liquid source splashed toward the second pipe due to bubbling the carrier gas through the liquid source, and for allowing the source gas and the carrier gas to pass through the blocking member.

Turning back to FIG. 2, the liquid source-supplying unit 150 may supply the liquid source 112 to the sealed chamber 110. The liquid source-supplying unit 150 may include a second tank 151, a third pipe 152 and a third valve 153.

The second tank 151 may contain the liquid source. The liquid source in the second tank 151 may be supplied to the sealed chamber 110. By way of example only, the liquid source in the second tank 151 may include an organic metal compound that may be substantially same as that of the liquid source in the sealed chamber 110.

The third pipe 152 may be connected between the second tank 151 and the sealed chamber 110. The third pipe 152 may penetrate the upper face of the sealed chamber 110 and extend into the sealed chamber 110. When the liquid source is provided to the sealed chamber 110 through the third pipe 152, the liquid source may collide against the liquid source 112 in the sealed chamber 110 so that the liquid source may be splashed. To reduce the splashing of the liquid source, the third pipe 152 may extend into the sealed chamber 110 and dip into the liquid source 112.

The third valve 153 may be installed in a portion of the third pipe 152 at the outside of the sealed chamber 110. The third valve 153 may open and close the third pipe 151. The third valve 153 may be opened and closed in accordance with a level of the liquid source 112 in the sealed chamber 110. By way of example only when the level of the liquid source 112 in the sealed chamber 110 is less than a lowest reference level, the third valve 153 may be opened so that the liquid source in the second tank 151 may flow into the sealed chamber 110 through the third pipe 152. When the level of the liquid source 112 in the sealed chamber 110 is more than a highest reference level, the third valve 153 may be closed so that the liquid source in the second tank 151 may not be provided to the sealed chamber 110 through the third pipe 152.

The level of the liquid source 112 in the sealed chamber 110 may be measured by a direct measurement method using a float (for example) or an indirect measurement method using physical phenomenon such as a pressure, sound, etc.

In the example embodiments, the blocking member 140 or 240 may block the liquid source 112 that may be splashed toward the second pipe 131 so that the second pipe 131 may not be smeared with the splashed liquid source 112. Thus, the second pipe 131 may not be clogged with the splashed liquid source. Thus, the source gas may be smoothly supplied into the process chamber 170 through the second gas-supplying unit 130 so as to reduce the chances of a failure of a CVD process.

The source gas-supplying unit 100 may operate as follows.

The third valve 153 of the liquid source-supplying unit 150 may be opened to provide the liquid source in the second tank 151 to the sealed chamber 110 through the third pipe 152. When the level of the liquid source 112 reaches the highest reference level, the third valve 153 may be closed. The heater 160 may heat the liquid source 112 in the sealed chamber 110.

The first valve 123 of the first gas-supplying unit 120 may be opened to provide the sealed chamber 110 with the carrier gas in the first tank 121 through the first pipe 122. The first pipe 122 may be dipped into the liquid source 112 in the sealed chamber 110 so that the carrier gas may be bubbled through the liquid source 112.

When the liquid source 112 is bubbled by the carrier gas, the liquid source 112 may be splashed. The blocking structure 140 may block the liquid source 112 splashed toward the position where the second pipe 131 may be connected to the sealed chamber 110. Thus, the second pipe 131 may not become smeared with the splashed liquid source. As a result, the cross sectional area of the second pipe 131 may be maintained. Further, the chances of the second pipe 131 becoming clogged with the splashed liquid source may be reduced.

The bubbled liquid source 112 may be evaporated to generate the source gas. The source gas and the carrier gas for carrying the source gas may be supplied to the second pipe 131 through the space between the inner wall of the sealed chamber 110 and the blocking structure 140. The second valve 132 may be opened to provide the process chamber 170 (where the CVD process may be carried out) with the source gas and the carrier gas through the second pipe 131.

A metal layer may be formed on the wafer using the source gas in the process chamber 170. The kind of the metal layer formed on the wafer may vary in accordance with a kind of the liquid source 112.

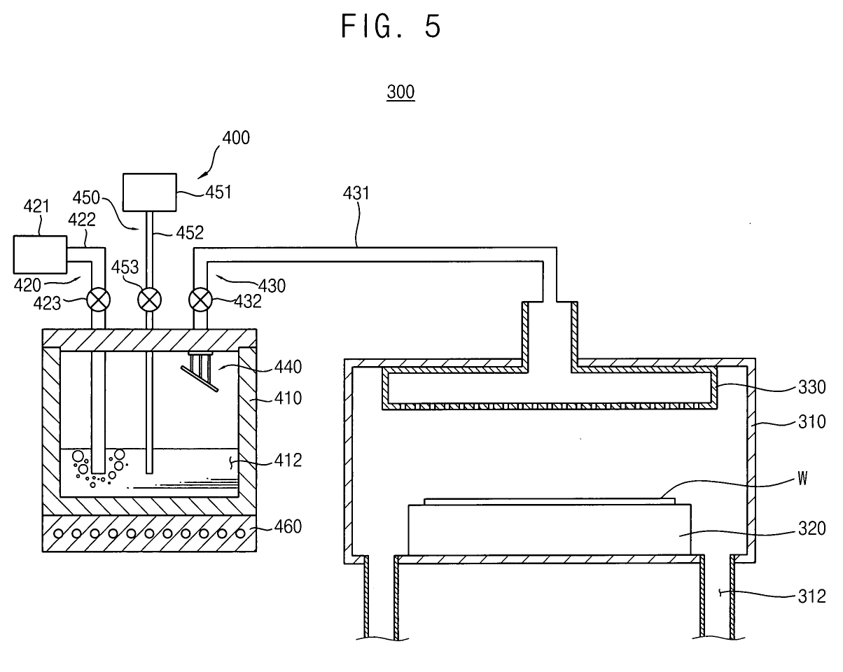

FIG. 5 is a cross sectional view of a chemical vapor deposition (CVD) apparatus in accordance with another example, non-limiting embodiment of the present invention.

Referring to FIG. 5, the CVD apparatus 300 may include a process chamber 310, a stage 320, a showerhead 330 and a source gas-supplying unit 400.

The process chamber 310 may provide a space where a CVD process may be performed. By way of example only, the process chamber 310 may have a cylindrical shape, a rectangular parallelepiped shape, etc. An exhaust pipe 312, which may exhaust a remaining gas that may be generated in the CVD process, may be connected to a lower face of the process chamber 310. A door (not shown), which may provide access for loading the wafer W into the process chamber 310, may be provided on a sidewall of the process chamber 310.

The stage 320, which may support the wafer W, may be arranged on the lower face of the process chamber 310. The stage 320 may support the wafer W in a horizontal state. The stage 320 may have a disk shape (for example) that has a size for sufficiently supporting the wafer W.

A lift pin (not shown), which may be for loading/unloading the wafer W, may be slidably inserted into the stage 320 in a vertical direction.

The showerhead 330 may be installed beneath an upper face of the process chamber 310 to face the stage 320. The showerhead 330 may distribute the source gas into the process chamber 310 and onto the wafer W to form a layer on the wafer W.

The source gas-supplying unit 400 may include elements substantially similar to those of the source gas-supplying unit 100 in FIG. 2. In FIG. 5, the component parts of the source gas-supplying unit 400 have been designated with references characters that have been increased by 300 (as compared to the references characters associated with the same component parts depicted in FIG. 2). For example, the first gas-supplying unit 420 of FIG. 5 corresponds to the first gas-supplying unit 120 of FIG. 2. Thus, for convenience, a detailed description of the source gas-supplying unit 400 may be omitted.

The second pipe 431 in the source gas-supplying unit 400 may not be clogged with the splashed liquid source so that the source gas may be smoothly supplied to the process chamber 310. Thus, the chances of failure of the CVD process performed using the CVD apparatus 300 may be reduced.

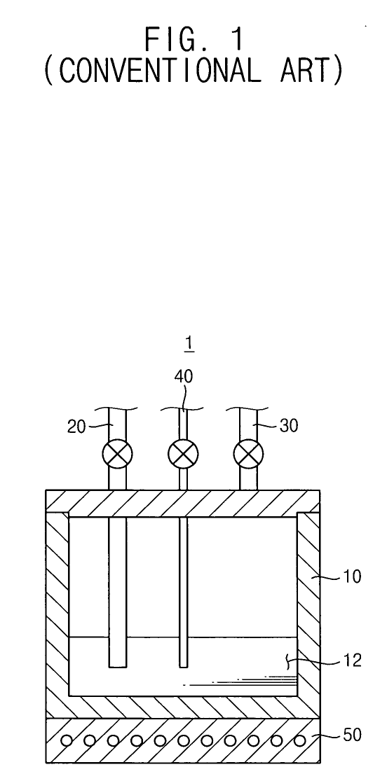

Consider the following. Comparative layers were formed by a CVD process using the conventional source gas-supplying unit 1 depicted in FIG. 1. Here, MPA was used as the liquid source. A source gas was formed using the MPA in the conventional source-gas supplying unit. The source gas was provided to a process chamber. A CVD process was carried out for a time of 30 seconds in the process chamber to form a layer on each of a plurality of wafers.

Example layers were formed by a CVD process using the example source gas-supplying unit 100 depicted in FIG. 2. Again, MPA was used as the liquid source. A source gas was formed using the MPA in the source-gas supplying unit 100 in FIG. 2. The source gas was provided to a process chamber. A CVD process was carried out for a time of 30 seconds in the process chamber to form a layer on each of a plurality of wafers.

The CVD processes performed using the conventional and example source gas-supplying units were evaluated as follows.

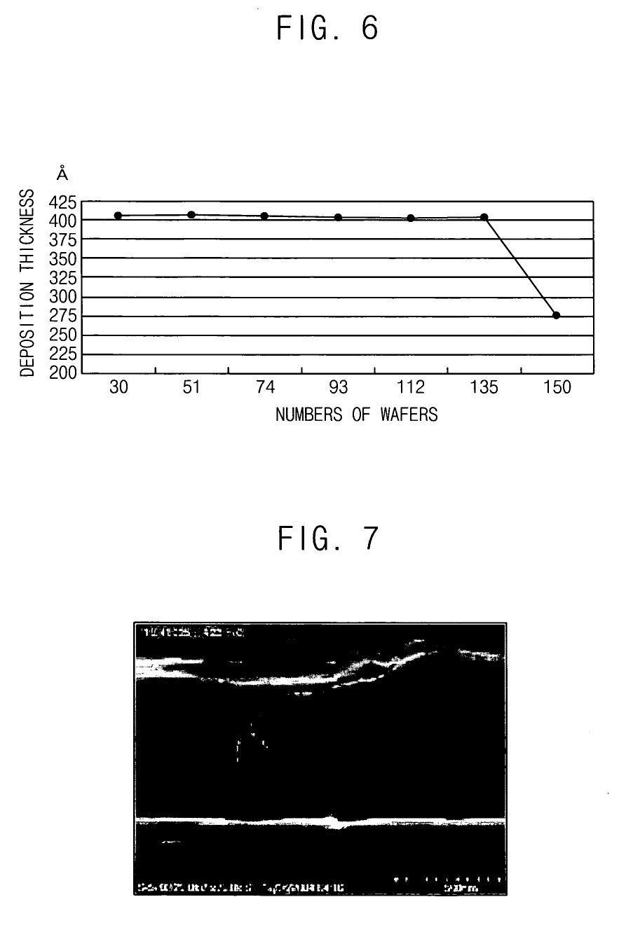

FIG. 6 is a graph illustrating a deposition thickness of the comparative layer per the number of a wafer on which a deposition process is carried out using the conventional source gas-supplying unit 1 in FIG. 1, and FIG. 7 is an image from a scanning electron microscope (SEM) of the comparative layer on the wafer that is formed using the conventional source-gas supplying unit 1 in FIG. 1.

As shown in FIG. 6, each of the comparative layers formed on a first wafer to a one hundred thirty-fifth wafer has a thickness of about 400 Å. However, the comparative layer formed on the one hundred fiftieth wafer has a thickness of about 275 Å, which is thinner than that of the comparative layers on the previous wafers. This may be caused (at least in part) by an irregular flow of the source gas to the process chamber due to the liquid source accumulating on the pipe for supplying the source gas.

Further, as shown in FIG. 7, voids may be generated in the comparative layer. As a result, it can be noted that the CVD process using the conventional source gas-supplying unit may perform abnormally over time.

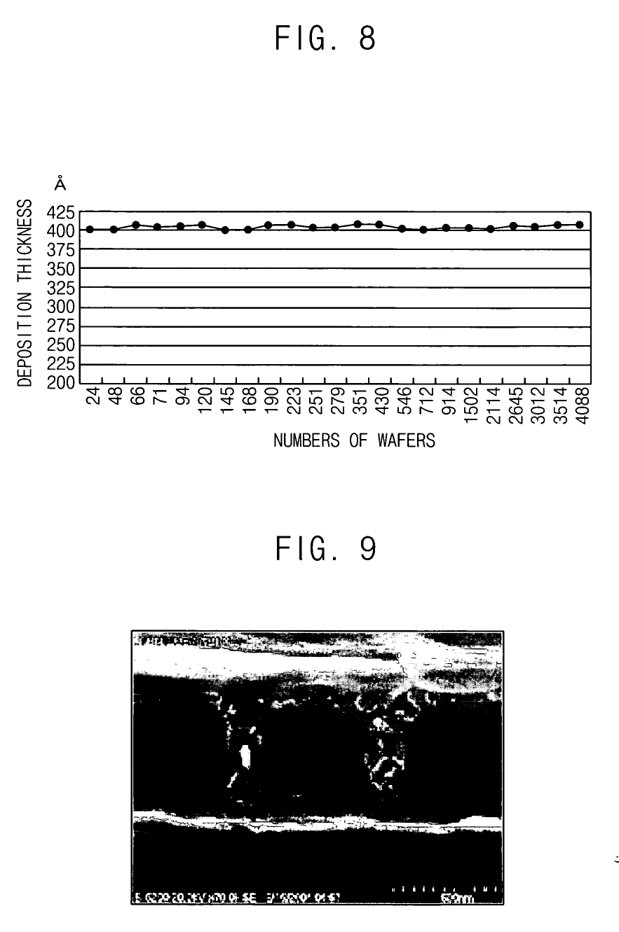

FIG. 8 is a graph illustrating a deposition thickness of an example layer per the number of a wafer on which a deposition process is carried out using the source gas-supplying unit 100 in FIG. 2, and FIG. 9 is an image from a scanning electron microscope (SEM) of an example layer on the wafer that is formed using the source-gas supplying unit 100 in FIG. 2.

As shown in FIG. 8, each of the example layers formed on a first wafer to a four thousandth wafer has a thickness of about 400 Å. Thus, it can be noted that the blocking structure blocks the liquid source splashed toward the pipe so that the source gas may be smoothly and regularly provided through the pipe and into the process chamber.

Further, as shown in FIG. 9, voids may not be generated in the layer. As a result, it can be noted that the CVD process using the source gas-supplying unit according to an example embodiment of the present invention may perform normally over time.

When the CVD process is carried out on the wafers using the conventional source gas-supplying unit, the more wafers are processed, the thinner the thicknesses of the layers may become. Thus, the CVD process may be suspended to exchange the conventional source gas-supplying unit for a new one. As a result, the CVD process may be delayed.

However, when the CVD process is carried out on the wafers using the source gas-supplying unit of the present invention, the thickness of the layers may be maintained.

The blocking structure may block the liquid source that may be splashed toward the second pipe due to the bubbling to prevent the splashed liquid source from being smeared on the second pipe for supplying the source gas and the carrier gas. Thus, the second pipe may not be clogged with the splashed liquid source. As a result, the source gas may smoothly flow into the process chamber so that the CVD process may be carried out as desired.

Further, because the second pipe may not be clogged with the splashed liquid source, a period for exchanging the source gas-supplying unit may be prolonged. A suspension time of the CVD process due to the clogging of the second pipe may be shortened.

Furthermore, layers having a uniform thickness may be formed on numerous wafers using the source gas-supplying unit according to example embodiments of the present invention.

Having described example, non-limiting embodiments of the present invention, it will be appreciated that numerous modifications and variations can be made by persons skilled in the art in light of the above teachings. It is therefore to be understood that changes may be made in the example embodiments of the present invention without departing from the scope and the spirit of the invention defined by the appended claims.

What is claimed is:

1. A source gas-supplying unit comprising:
a chamber for receiving a liquid source;
a first pipe extended into the chamber to dip into the liquid source, the first pipe for supplying a carrier gas that is bubbled through the liquid source to generate a source gas;
a second pipe connected to the chamber, the second pipe for supplying the source gas and the carrier gas to a process chamber; and
a blocking structure arranged in the chamber, the blocking structure blocking the liquid source splashed toward the second pipe.

2. The source gas-supplying unit of claim 1, wherein the blocking structure is inclined.

3. The source gas-supplying unit of claim 1, wherein the blocking structure is positioned adjacent to a portion of the chamber where the second pipe is connected.

4. The source gas-supplying unit of claim 1, wherein the blocking structure may be fabricated from one of a stainless steel and a ceramic.

5. The source gas-supplying unit of claim 1, wherein the blocking structure is coated with a coating material.

6. The source gas-supplying unit of claim 5, wherein the coating material comprises TEFLON.

7. The source gas-supplying unit of claim 1, wherein the liquid source has a viscosity coefficient of no more than about 30 cP.

8. The source gas-supplying unit of claim 1, wherein the liquid source comprises a metal organic compound.

9. A chemical vapor deposition (CVD) apparatus comprising:
a process chamber for receiving a wafer; and
a source gas-supplying unit including
a chamber for receiving a liquid source,
a first pipe extended into the chamber to dip into the liquid source, the first pipe for supplying a carrier gas that is bubbled through the liquid source to generate a source gas,
a second pipe connected to the sealed chamber, the second pipe for supplying the source gas and the carrier gas to the process chamber, and
a blocking structure arranged in the chamber, the blocking structure blocking the liquid source splashed toward the second pipe.

10. The CMP apparatus of claim 9, wherein the liquid source has a viscosity coefficient of no more than about 30 cP.

11. The CMP apparatus of claim 9, wherein the liquid source comprises a metal organic compound.

12. A source gas-supplying unit comprising:
a chamber to contain a liquid;
a first conduit extended into the chamber, the first conduit to supply a carrier gas into the liquid to generate a source gas;
a second conduit having an end connected to the sealed chamber; and
means for deflecting liquid splashed toward the second conduit.

13. The source gas-supplying unit of claim 12, wherein the means for deflecting includes a circular plate.

14. The source gas-supplying unit of claim 13, wherein the circular plate is inclined with a wall of the chamber.

15. The source gas-supplying unit of claim 13, wherein the circular plate is spaced apart from the chamber.

16. The source gas-supplying unit of claim 12, wherein the means for deflecting includes a blocking member having an arcuate profile.

17. The source gas-supplying unit of claim 16, wherein the blocking member is spaced apart from the chamber.

18. The source gas-supplying unit of claim 12, wherein the second conduit is connected to a process chamber.

19. The source gas-supplying unit of claim 12, further comprising a third conduit connected to the chamber to supply the liquid to the chamber.

20. The source gas-supplying unit of claim 19, wherein the third conduit extends into the chamber.
